(19) United States
(12) Patent Application Publication
(10) Pub. No.: US 2002/0189853 A1
(43) Pub. Date: Dec. 19, 2002

(54) BGA substrate with direct heat dissipating structure

(75) Inventor: Shih-Ping Hsu, Tao Yuan (TW)

Correspondence Address: Raymond Sun, Law Offices of Raymond Sun, 12420 Woodhall Way, Tustin, CA, 92782, US

(73) Assignee: Phoenix Precision Technology Corp.

(21) Appl. No.: 09/957,372

(22) Filed: Sep. 20, 2001

Related U.S. Application Data
(63) Continuation-in-part of application No. 09/882,725, filed on Jun. 15, 2001, now abandoned.

(51) Int. Cl. H05K 7/20

(52) U.S. Cl. 174/252; 174/264; 361/720; 361/719

(57) ABSTRACT

BGA substrate with direct heat dissipating structure The present invention discloses a structure of BGA substrate with direct heat-dissipating structure, said structure comprising: a heat spreader, no less than one insulating resin layer, an upper circuit layer, a lower circuit layer, and a plurality of electrically-conducting plugs. The heat spreader comprises a body part, a loading part, and a junction part. The loading part is the upper region of heat spreader. The junction part is the lower region of the heat spreader. The periphery of said junction part extends outward for forming a protruding edge. The body part is embedded into the central region of the substrate. The upper circuit layer is formed on the surface of said resin layer. The lower circuit layer is formed on lower surface of said resin layer and comprises a plurality of solder pads. The upper and lower circuit layers are conducted by electrically conductive plugs. The heat generated from chip is dissipated by heat spreader instead of heat-conducting plugs in traditional art. The cross sectional area of heat spreader is larger than the heat-conducting plug, which enhances the performance of heat dissipation.

### FIELD OF THE INVENTION

The present invention relates generally to the structure of BGA substrate with direct heat-dissipating structure, particularly to the BGA substrate with high heat-dissipating efficiency.

### BACKGROUND OF THE INVENTION

Referring to FIG. 1, it is a cross sectional view illustrating the structure of BGA substrate 10 according to the first traditional art. There are a copper plate 11, an upper resin layer 12, an upper circuit layer 13, a lower resin layer 14, a lower circuit layer 15, a plurality of plated through holes (PTH) 16, and a plurality of heat-conducting plugs 17 in the BGA substrate 10.

The copper plate 11 used as the heat sink of the substrate 10 is in the central region of the substrate 10. So that, the heat generated from the chip 20 is dissipated through the copper plate 11 to the outside. In the periphery of the copper plate 11, there is a plurality of vias 112 penetrating the copper plate 11.

The upper resin layer 12 is laminated on the upper surface of the copper plate 11, and the lower resin layer 14 is laminated on the lower surface of the copper plate 11. The via 112 of the copper plate 11 is filled with the insulating resin by laminating the upper and lower resin layer 12, 14.

The upper circuit layer 13 is formed on the surface of the upper resin layer 12, and the upper circuit layer 13 comprises a plurality of wiring-pads 132 plated with a Ni—Au layer thereon. Furthermore, a solder mask 18 covers the surface of the upper circuit layer 13 for the protection of the upper circuit layer 13 with the wiring-pad 132 exposed.

The lower circuit layer 15 is formed on the surface of the lower resin layer 14, and the lower circuit layer 14 comprises a plurality of solder pads 152 plated with the Ni—Au layer thereon. Usually, the surface of the lower circuit layer 15 is covered with a layer of solder mask 19 for the protection of the lower circuit layer 15 with the solder pads 152 exposed.

The plated through holes (PTH) 16 punches through the upper resin layer 12, the via 112 of the copper plate 11, and the lower resin layer 14 to conduct the upper and lower circuit layer 13,15. The plated through hole 16 is smaller than via 112 of the copper plate 11 in diameter. The insulating resin is around the plated through hole to separate the plated through hole (PTH) 16 and the via 112 for avoiding short-circuit.

The plural heat-conducting plugs 17 punch through the upper resin layer 12, the copper plate 11, and the lower resin layer 14 to contact the bottom of the chip 20 directly.

In the first traditional art, the chip 20 is positioned on the surface of the upper resin layer 12, and the bottom of the chip 20 contacts the heat-conducting plug 17 directly in the packaging process. The wiring-pad 132 of the upper circuit layer 13 on the substrate 10 is coupled with the circuit layout of the chip 20 by a plurality of golden wires 21. Then, the chip 20 and the golden wire 21 are protected by the epoxy 22. The surface of the solder pad 152 on the lower circuit layer 15 is welded with a plurality of solder balls 23. Afterward, the solder ball 23 is coupled with the circuit on the circuit board (not shown in the figure).

However, there are some disadvantages, like the lower heat-conducting efficiency and the complication of the manufacturing of the substrate 10 in the first traditional art.

(a) The first reason is that the heat-conducting plugs 17 transmit the heat from the chip 20 to the copper plate 11, the circuit board, and outside. However, the cross sectional area of the heat-conducting plugs 17 for chip is limited, and the material of the epoxy 22 and the upper resin layer 12 is poorer for the heat conducting., Therefore, the heat-dissipating efficiency of the package device is lower, and the chip 20 is easily unstable while operating.

(b) Tie second reason is that the manufacturing of the heat-conducting plugs 17 of the substrate 10 comprises drilling, plating copper, and plugging hole. The processes are complicated and very costly. If the hole is filled not completely, which results in forming voids easily. There will be a “Popcorn” phenomenon in packaging process.

So, in the field of packaging chip, people are devoted into improving the heat-dissipating efficiency to upgrade the quality and the competitiveness of the product.

Referring to the FIG. 2, it is the cross sectional view of the structure of a BGA substrate 30 according to the second traditional art. In the first traditional art, it is the Die Up type with lower heat dissipating efficiency. The second traditional art with Cavity Down type is disclosed against the disadvantages of the first traditional art.

The BGA substrate 30 comprises heat spreader 31, an insulating layer 32, and a circuit layer 33. The heat spreader 31 is a copper plate. The insulating layer 32 comprises a recess 321 for mounting the chip 40 therein. The heat spreader 31 is attached to the insulating layers 32. The circuit layer 33 is formed on the surface of the insulating layer 32, comprising a plurality of the wiring-pads 332 and solder pads 334 plated with the Ni—Au layer thereon. The surface of the circuit layer 33 is covered with a solder mask 34 to protect the circuit layer 33 with the solder pads 334 and wiring-pads 332 exposed.

In the packaging process of the substrate 30, the chip 40 is mounted within the recess 321 of the insulating layer 32. The circuit layout of the chip 40 is coupled with the wiring-pad 332 of circuit layer 33 by a plurality of golden wires 41. The surface of the chip 40 and the periphery of the golden wire 41 are protected with a layer of the epoxy 42. Then, the solder pads 334 are welded with a plurality of solder balls 43 connected with the circuit on the circuit board (not shown on the figure).

The heat-dissipation performance in the second traditional art is better than that of the first traditional art. However, there are still some disadvantages. Firstly, in the Cavity Down type of the substrate 30, the chip 40 and the solder ball 43 are positioned on the same side, which is different from the Die Up type of the first traditional art. So, there are some changes needed for the packaging process of the Cavity Down type substrate. Moreover, the chip 40 and solder ball 43 are designed on the same side of the substrate 30, so the space of the upper surface of the BGA substrate 30 not only provides the area for the welding solder ball 43, but also for mounting the chip 40. Therefore, the number of solder balls 43 placed is decreased, and the substrate 30 could function improperly. Secondly, the manufacturing is very complicated, unreliable, and very expensive, because the way to form encapsulant by filling epoxy 42 is processed one by one, not by group.

### SUMMARY OF THE INVENTION

The present invention provides a BGA substrate of high heat-dissipating efficiency with direct heat-dissipating structure. The heat of the substrate is dissipated by heat spreader instead of heat-conducting plugs, so the efficiency and the stability of the chip in operation are enhanced, and there are fewer popcorn phenomenons.

Another object of the present invention is to provide a Die up type BGA substrate with direct heat-dissipating structure. More solder balls can be formed in the present invention than the second traditional art of the Cavity Down type. There is no change needed in the packaging process, and the substrate is more capable.

In the present invention, the BGA substrate with direct heat-dissipating structure comprises a heat spreader, more than one resin layer, an upper circuit layer, a lower circuit layer and a plurality of electrically conductive plugs.

The heat spreader is a metal plate and comprises a body part, a loading part, and a junction part. The loading part is the upper region of the heat spreader. The junction part is the lower region of the heat spreader. The periphery of the junction part extends outward for forming a protruding edge, which enhances the adhesion ability of heat spreader to substrate. The resin layer surrounds the outside of the body part of the heat spreader. The heat spreader is embedded into the central part of the resin layer. The upper circuit layer with a plurality of wiring-pads thereon is positioned on the surface of the resin layer, and the surface of the upper circuit layer is covered with a protection layer with the wiring-pad exposed.

The lower circuit layer is positioned on the lower surface of the resin layer, and the lower circuit layer comprises a plurality of solder pads. Usually, the surface of the lower circuit layer is covered by a protection layer with the solder pad exposed. The electrically conductive plugs pass through the resin layer and electrically connect the upper and lower circuit layer.

In another embodiment, there are two resin layers around the upper and lower periphery of the body part of the heat spreader. Plural insulating holes pass through the upper resin layer, heat spreader, and lower resin layer. The electrically conductive plugs pass through the insulating hole. The upper and lower circuit layers are conducted by plural electrically conductive plugs. The electrically conductive plug is smaller than the insulating hole in diameter to avoid short-circuiting.

The chip is mounted on the loading part of the heat spreader in the packaging process. The wiring-pad of the upper circuit layer is coupled with the circuit layout of the chip by the golden wires. The surface of the solder pads on the lower circuit layer is welded with a plurality of solder balls. Afterward, is the solder balls are combined with the circuit board. The junction part of the heat spreader is welded on the circuit board by the tin paste. The surface of substrate around the chip and the proximity of the golden wire are covered with a layer of the epoxy to protect the chip from outside effect.

The heat spreader in the present invention transmits the heat from the chip to outside. The cross sectional area for heat spreader is larger than the heat-conducting plug, so the present invention is a better heat-dissipating method than the prior art. The efficiency and stability of the operating chip are enhanced, and there're fewer popcorn phenomenons. Moreover, the BGA substrate is Die up type in the present invention with larger area for soldering solder balls compared with the second traditional art. The substrate is more capable in present invention, and there's no changes needed for the substrate in the packaging process.

### BRIEF DESCRIPTION OF THE DRAWINGS

For a better understanding on the objects, advantages and capabilities of the present invention, reference is made to the following disclosure, appended claims in connection with the accompanying drawings, in which:

FIG. 1 is a cross sectional view illustrating the structure of BGA substrate according to the first traditional art.

FIG. 2 is a cross sectional view illustrating the structure of BGA substrate according to the second traditional art.

FIG. 3 is a cross sectional view illustrating the BGA substrate with direct heat-dissipating structure according to the first embodiment in the present invention.

FIG. 4 is a cross sectional view illustrating the BGA substrate with direct heat-dissipating structure according to the second embodiment in the present invention.

FIG. 5 is a cross sectional view illustrating the BGA substrate with direct heat-dissipating structure according to the third embodiment in the present invention.

FIG. 6 is a cross sectional view illustrating the BGA substrate with direct heat-dissipating structure according to the fourth embodiment in the present invention.

FIG. 7 is a cross sectional view illustrating the BGA substrate with direct heat-dissipating structure according to the fifth embodiment in the present invention.

FIG. 8 is a cross sectional view illustrating the BGA substrate with direct heat-dissipating structure according to the sixth embodiment in the present invention.

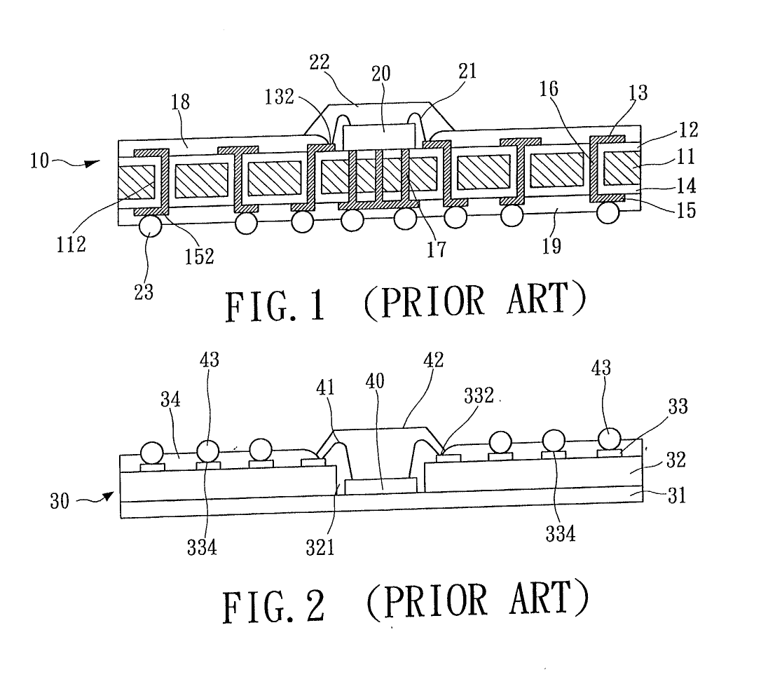

### DETAILED DESCRIPTION OF THE PREFERRED EMBODIMENT

Hereinafter, the preferred embodiments of the invention will be described with reference to accompany drawing wherein like reference numerals designate like parts, respectively.

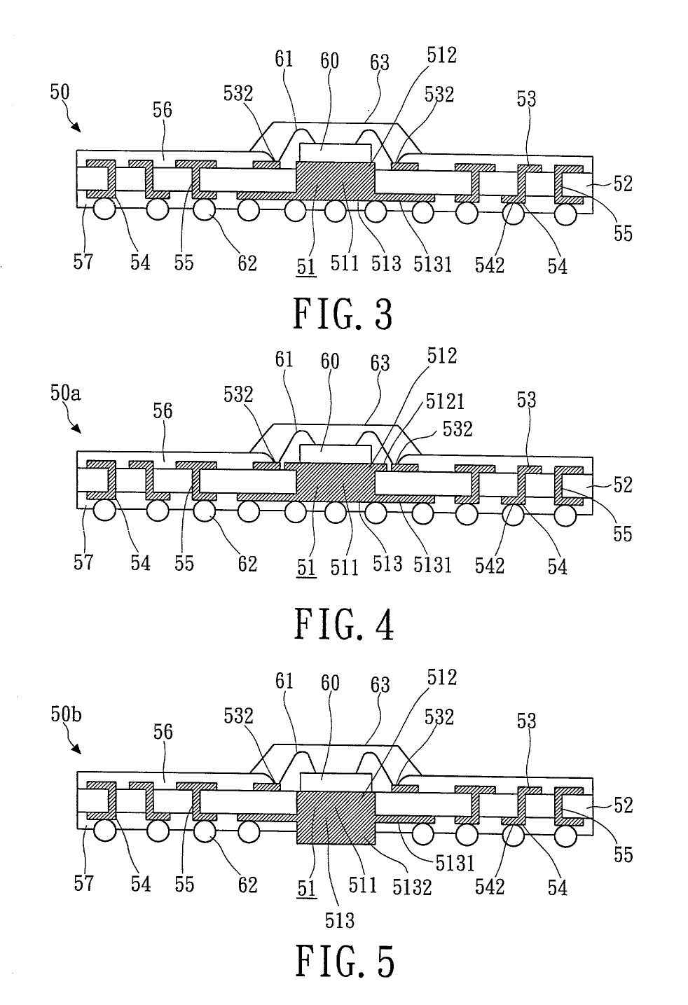

Referring to FIG. 3, it is a cross sectional view of the first embodiment of the present invention illustrating the BGA substrate 50 with direct heat-dissipating structure. The BGA substrate 50 comprises a heat spreader 51, a resin layer 52, an upper circuit layer 53, a lower circuit layer 54, and a plurality of electrically conductive plugs 55.

The heat spreader 51 can conduct heat and electricity, comprising a body part 511, a loading part 512, and a junction part 513. The loading part 512 is the upper region of the heat spreader 51, and the junction part 513 is the lower region of the heat spreader 51. The periphery of the junction part 513 extends outward to form a protruding edge 5131.

The resin layer 52 surrounds the outside of the body part 511 of the heat spreader 51. The upper circuit layer 53 with a plurality of wiring-pads 532 thereon is positioned on the surface of the resin layer 52, and the surface of the upper circuit layer 53 is covered with a solder mask 56 with the wiring-pads s 532 exposed.

The lower circuit layer 54 is formed on the lower surface of the resin layer 52, and the lower circuit layer 54 comprises a plurality of solder pads 542. Usually, the surface of the lower circuit layer 54 is covered by a layer of solder mask 57 with the solder pads 542 being exposed. The electrically conductive plugs 55 are through the resin layer 52 and electrically connect the upper and lower circuit layer 53,54.

In the first embodiment of FIG. 3, the chip 60 is mounted on the loading part 512 of the heat spreader 51 in the packaging process. The wiring-pad 532 of the upper circuit layer 53 is coupled with the circuit layout of the chip 60 by a plurality of golden wires 61. The surface of the solder pads 542 on the lower circuit layer 54 is soldered with a plurality of solder balls 62. Afterward, the solder balls 62 are coupled with the circuit board. The junction part 513 of the heat spreader 51 is soldered on the circuit board by the tin paste (not shown in the figure). The surface of substrate 50 around the chip 60 and the golden wire 61 are covered with a layer of the epoxy 63 to protect the chip 60 from outside effect.

Referring to FIG. 3, the junction part 513 of the heat spreader 51 is connected with the circuit board by plural solder balls 62. Plural solder pads plated with Ni—Au layer thereon (not shown in the figure) are located on the surface of lower circuit layer 54 and junction part 513 of the heat spreader 51. The surface of the lower circuit layer 54 and the junction part 513 of the heat spreader 51 are covered with solder masks 57 with the solder pads being exposed. The solder balls 62 are soldered with the solder pads 542. The junction part 513 is connected with the circuit board by the solder balls 62.

Referring to FIG. 4, it is the cross sectional view of the second embodiment of the present invention illustrating the BGA substrate 50a with direct heat-dissipating structure. The structure of substrate 50a is almost the same with that of first embodiment. In FIG. 4, the most difference with FIG. 3 is that the periphery of the loading part 512 extends outward to form a protruding edge 5121. The side view of the heat spreader 51 looks like a “I” shape for the purpose to strengthen the structure of the whole substrate 50a to avoid being bended by external forces. The process of packaging chip 60 and connecting the substrate 50a to the circuit board are the same with that of the first embodiment.

Referring to FIG. 5, it is the cross sectional view of the third embodiment is of the present invention illustrating the BGA substrate 50b with direct heat-dissipating structure. The structure of substrate 50b is almost the same with that of first embodiment, and no more details will be described respectively wherein like reference numerals designate like parts. In FIG. 5, the most difference with FIG. 3 is that the junction part 513 extends downward to form a protruding edge 5132. The resin layer 52 surrounds the periphery of the body part 511 of heat spreader 51. The heat spreader 51 is embedded in the resin layer 52 and the upper circuit layer 53 is formed on the upper surface of the resin layer 52. The lower circuit layer 54 is formed on the lower surface of the resin layer 52. The process of packaging chip 60 and connecting the substrate 50b to the circuit board are the same with that of the first embodiment.

Referring to FIG. 6, it is the cross sectional view of the fourth embodiment of the present invention illustrating the BGA substrate 50c with direct heat-dissipating structure. The BGA substrate 50c is applied in the Multi-Chip 60 Modulus. The structure of substrate 50c is almost the same with that of first embodiment, and no more details will be described respectively wherein like reference numerals designate like parts. In FIG. 6, the most difference with FIG. 3 is that pluralities of chips 60 are mounted on the same substrate 50c. The substrate 50c is more capable, when the chips are more. The process of packaging chip 60 and connecting the substrate 50c to the circuit board are the same with that of the first embodiment.

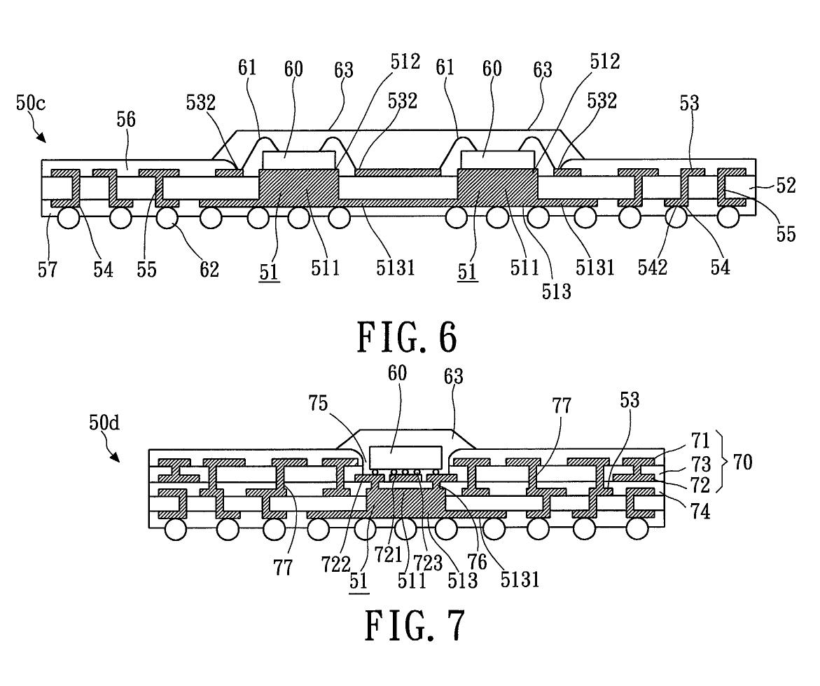

Referring to FIG. 7, it is the cross sectional view of the fifth embodiment of the present invention illustrating the BGA substrate 50d with direct heat-dissipating structure. In FIG. 7, the most difference with FIG. 3 is that two-layered circuit 70 is formed on the surface of the upper circuit layer 53 and one resin layer 74 is positioned between upper circuit layer 53, and two-layered circuit 70. The two-layered circuit 70 with a sandwich structure comprises a first circuit layer 71, a second circuit layer 72, and a resin layer 73 interposed between the first circuit layer 71 and the second circuit layer 72. The two-layered circuit 70 comprises a recess 75 with the depth reaching the second circuit layer 72. The second circuit layer 72 comprises electric-conducting circuit 721 and a heat-conducting circuit 722. Plural metal bumps 723 are formed on the surface of the electric-conducting circuit 721 and the heat-conducting circuit 722, respectively. The heat-conducting circuit 722 is connected with the loading part 511 of the heat spreader 51 with a plurality of heat-conducting plugs 76.

In the process of packaging chip 60 to the substrate 50d, the chip 60 is mounted within the recess 75 of the substrate 50d. The circuit layout of the chip 60 is coupled with the second circuit layer 72 of the two-layered circuit 70. The heat generated from the chip 60 is transmitted through the heat-conducting plug 76 and heat spreader 51 to the outside. The process of connecting the substrate 50d to the circuit board is the same with that of the first embodiment.

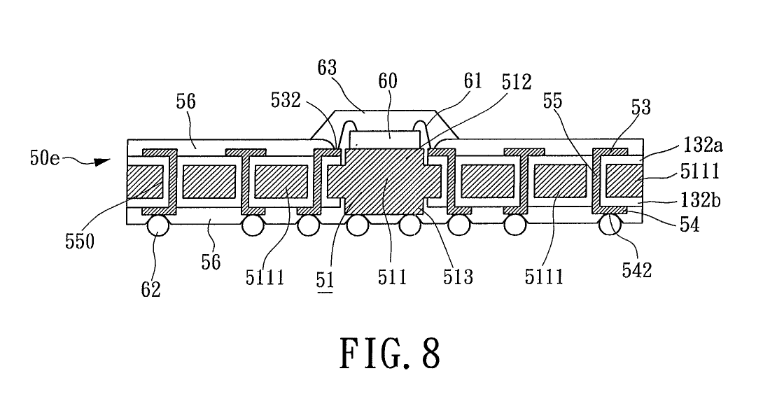

There is another preferred embodiment. Referring to FIG. 8, it is the cross sectional view of the sixth embodiment of the present invention illustrating the BGA substrate 50e with direct heat-dissipating structure. The heat spreader 51 comprises a body part 511, a loading part 512, and a junction part 513. The body part 511 extends outward for forming a whole heat-dissipating plate 5111. The upper and lower surfaces of the heat-dissipating plate 5111 are coated with two resin layers 132a, 132b. Each of the upper and lower resin layers 132a, 132b has an “opening”, which is sufficiently large to accommodate the loading part 512 and the junction part 513 respectively. A plurality of insulating holes 550 pass through the upper resin layer 132a, heat dissipating plate 5111, and lower resin layer 132b. Electrically conductive plugs 55 pass through the insulating holes 550. The upper and lower circuit layer 53, 54 are conducted by electrically conductive plugs 55. The electrically conductive plugs 55 are smaller than the insulating hole in diameter in order to avoid contacting each other directly. So there is no short-circuit, and that the heat spreader 51 is designed to extend outward for forming whole heat-dissipating plate 5111. The heat-dissipating efficiency can be enhanced.

From the above description, there are some characteristics and advantages of the present invention.

Firstly, the cross sectional area of the heat spreader 51 of the present invention is much larger than the cross sectional area of the heat-conducting plug 17 in the traditional art. So, the heat-dissipating efficiency is enhanced much.

Secondly, since the structure of the present invention results in simpler fabrication process, the heat spreader 51 is manufactured with a great quantity and then embedded into the resin layer 52 or the upper resin and lower resin layer 132a, 132b, which does not need drilling, plating copper and plugging hole in the traditional art of making heat conducting plugs 17, the cost is lower, and the popcorn problem could be overcome.

While the invention has been described in terms of preferred embodiments of BGA substrate with the direct heat-dissipating structure, various alternatives and modifications can be devised by those who skilled in the art without departing from the invention. For instance, the upper and lower circuit layer of the BGA substrate with direct heat-dissipating structure could be designed as single-layered or multi-layered, but each circuit layer could contact each other by plated through holes. So that the substrate could be used for every type of package. Accordingly, the present invention is intended to embrace all such alternatives, which fall within the scope of the appended claims.

The embodiments of the invention in which an exclusive property or privilege is claimed are defined as follows:

1. A structure of BGA substrate with direct heat-dissipating structure, said structure comprising:
a heat spreader, which comprising a body part, a loading part, and a junction part, said loading part is the upper region of the heat spreader, and said junction part is the lower region of the heat spreader, the periphery of said junction part extending outward for forming a protruding edge;
a resin layer, said resin layer surrounding the outside of said body part;
an upper circuit layer, which is formed on the upper surface of said resin layer;
a lower circuit layer, which is formed on the lower surface of said resin layer;
a plurality of electrically conducting plugs, passing through said resin layer and conducting said upper circuit layer and said lower circuit layer.

2. The BGA substrate with direct heat-dissipating structure of claim 1, wherein the periphery of said loading part extending outward for forming a protruding edge.

3. The BGA substrate with direct heat-dissipating structure of claim 1,wherein said junction part extending downward for forming a protruding edge.

4. A structure of BGA substrate with direct heat-dissipating structure, said structure comprising:
a heat spreader, which comprising a body part, a loading part, and a junction part, said loading part is the upper region of the heat spreader, and said junction part is the lower region of the heat spreader, the periphery of said body part extending outward for forming a whole heat-dissipating plate; a plurality of insulating holes forming at the proper position of the periphery region of said heat-dissipating plate;
an upper resin layer, the upside of the heat-dissipating plate is coated with said upper resin layer;
an upper circuit layer, which is formed on the surface of said upper resin layer;
a lower resin layer, the underside of the heat-dissipating plate is coated with said lower resin layer;
a lower circuit layer, which is formed on the surface of said lower resin layer; and
a plurality of electrically conductive plugs, said electrically conductive plugs passing through said upper resin layer, insulating holes of the heat-dissipating plate, and lower resin layer to conduct upper and lower circuit layer.

5. The BGA substrate with direct heat-dissipating structure of claim 1, the surface of said junction part is protected with a solder mask.

6. The BGA substrate with direct heat-dissipating structure of claim 2, the surface of said junction part is protected with a solder mask.

7. The BGA substrate with direct heat-dissipating structure of claim 4, the surface of said junction part is protected with a solder mask.

8. The BGA substrate with direct heat-dissipating structure of claim 1, wherein said upper circuit layer is a single-layered circuit.

9. The BGA substrate with direct heat-dissipating structure of claim 2, wherein said upper circuit layer is a single-layered circuit.

10. The BGA substrate with direct heat-dissipating structure of claim 3, wherein said upper circuit layer is a single-layered circuit.

11. The BGA substrate with direct heat-dissipating structure of claim 4, wherein said upper circuit layer is a single-layered circuit.

12. The BGA substrate with direct heat-dissipating structure of claim 1, wherein said upper circuit layer is a multi-layered circuit and each circuit layer of said multi-layered circuit is conducted by plural electrically-conducting plugs.

13. The BGA substrate with direct heat-dissipating structure of claim 2, wherein said upper circuit layer is a multi-layered circuit and each circuit layer of said multi-layered circuit is conducted by plural electrically-conducting plugs.

14. The BGA substrate with direct heat-dissipating structure of claim 3, wherein said upper circuit layer is a multi-layered circuit and each circuit layer of said multi-layered circuit is conducted by plural electrically-conducting plugs.

15. The BGA substrate with direct heat-dissipating structure of claim 4, wherein said upper circuit layer is a multi-layered circuit and each circuit layer of said multi-layered circuit is conducted by plural electrically-conducting plugs.

16. The BGA substrate with direct heat-dissipating structure of claim 1, wherein said lower circuit layer is a single-layered circuit.

17. The BGA substrate with direct heat-dissipating structure of claim 2, wherein said lower circuit layer is a single-layered circuit.

18. The BGA substrate with direct heat-dissipating structure of claim 3, wherein said lower circuit layer is a single-layered circuit.

19. The BGA substrate with direct heat-dissipating structure of claim 4, wherein said lower circuit layer is a single-layered circuit.

20. The BGA substrate with direct heat-dissipating structure of claim 1, wherein said low circuit layer is a multi-layered circuit and each circuit layer of said multi-layered circuit is conducted by plural electrically conducting plugs.

21. The BGA substrate with direct heat-dissipating structure of claim 2, wherein said low circuit layer is a multi-layered circuit and each circuit layer of said multi-layered circuit is conducted by plural electrically conducting plugs.

22. The BGA substrate with direct heat-dissipating structure of claim 3, wherein said low circuit layer is a multi-layered circuit and each circuit layer of said multi-layered circuit is conducted by plural electrically conducting plugs.

23. The BGA substrate with direct heat-dissipating structure of claim 4, wherein said low circuit layer is a multi-layered circuit and each circuit layer of said multi-layered circuit is conducted by plural electrically conducting plugs.

24. The BGA substrate with direct heat-dissipating structure of claim 4, wherein said upper resin layer has an “opening” sufficiently large to accommodate the loading part of said heat spreader.

25. The BGA substrate with direct heat-dissipating structure of claim 4, wherein said lower resin layer has an “opening” sufficiently large to accommodate the junction part of said heat spreader.
